(19) United States
(12) Patent Application Publication
(10) Pub. No.: US 2018/0174801 A1
(43) Pub. Date: Jun. 21, 2018

(54) APPARATUSES AND METHODS FOR SURFACE TREATMENT

(71) Applicant: ULVAC Technologies, Inc., Westford, MA (US)

(72) Inventors: Wei CHEN, Westford, MA (US); Kevin Michael MCCORMICK, Manchester, NH (US)

(73) Assignee: ULVAC Technologies, Inc., Westford, MA (US)

(21) Appl. No.: 15/387,311

(22) Filed: Dec. 21, 2016

(51) Int. Cl. H01J 37/32; B08B 7/00

(52) U.S. Cl. CPC H01J 37/3211; H01J 37/3244; H01J 2237/338; B08B 7/0035; H01J 2237/335; H01J 37/32183

(57) ABSTRACT

According to an exemplary embodiment, a surface treatment unit comprises a chamber, a process gas inlet configured to allow process gas to enter the chamber, a first and a second plasma source, and a first RF antenna inductively coupled to the first plasma source and a second RF antenna inductively coupled to the second plasma source. The first and second RF antennas are configured to simultaneously ignite a first and second plasma, and the first and second plasma sources are configured to simultaneously supply the first and second plasma to a work-piece within the chamber.

### INCORPORATION BY REFERENCE

All patents, patent applications and publications cited herein are hereby incorporated by reference in their entirety in order to more fully describe the state of the art as known to those skilled therein as of the date of the invention described herein.

### TECHNICAL FIELD

This technology relates generally to apparatuses and methods for surface treatment and work-piece processing.

### BACKGROUND

Front and back end semiconductor and display industries have recently needed large area surface treatments, such as surface cleaning, oxidation, among others. Therefore, there is a need for a high efficiency surface treatment with excellent process uniformity over large size wafer and other work-pieces.

### SUMMARY

According to an exemplary embodiment, a surface treatment unit comprises a chamber, a process gas inlet configured to allow process gas to enter the chamber, a first and a second plasma source, and a first RF antenna inductively coupled to the first plasma source and a second RF antenna inductively coupled to the second plasma source. The first and second RF antennas are configured to simultaneously ignite a first and second plasma, and the first and second plasma sources are configured to supply the first and second plasma to a work-piece within the chamber.

In some embodiments, the first and the second RF antenna are connected in parallel. In some embodiments, the first and the second RF antenna are configured to be connected to the same RF power supply and RF match unit. In some embodiments, the gas inlet is configured to distribute a process gas substantially evenly to the first and second plasma sources. In some embodiments, the surface treatment unit further comprises a third plasma source; and a third RF antenna inductively coupled to the third plasma source, wherein the third RF antenna is configured to ignite a third plasma, and wherein the third plasma source is configured to supply the third plasma to a work-piece within the chamber. In some embodiments, the first, second, and third plasma sources and the RF antennas are arranged in a triangle configuration.

In some embodiments, the first, second, and third plasma sources and the RF antennas are arranged in a linear configuration. In some embodiments, the surface treatment unit further comprises a fourth plasma source; and a fourth RF antenna inductively coupled to the fourth plasma source, wherein the fourth RF antenna is configured to ignite a fourth plasma, and wherein the fourth plasma source is configured to supply the fourth plasma to a work-piece within the chamber, and wherein the first, second, third, and fourth plasma sources and the RF antennas are arranged in a rectangular configuration. In some embodiments, the surface treatment unit further comprises a fourth plasma source; a fourth RF antenna inductively coupled to the fourth plasma source, wherein the fourth RF antenna is configured to ignite a fourth plasma, and wherein the fourth plasma source is configured to supply the fourth plasma to a work-piece within the chamber; a fifth plasma source; and a fifth RF antenna inductively coupled to the fifth plasma source, wherein the fifth RF antenna is configured to ignite a fifth plasma, and wherein the fourth plasma source is configured to supply the fourth plasma to a work-piece within the chamber, and wherein the first, second, third, fourth, and fifth plasma sources and the RF antennas are arranged in a pentagon configuration.

In some embodiments, the surface treatment unit further comprises a sixth plasma source; and a sixth RF antenna inductively coupled to the sixth plasma source, wherein the sixth RF antenna is configured to ignite a sixth plasma, wherein the sixth plasma source is configured to supply the sixth plasma to a work-piece within the chamber, and wherein the sixth plasma source and the sixth RF antenna are positioned within the pentagon configuration.

According to an exemplary embodiment, a method of processing a work-piece comprises simultaneously igniting a first and a second plasma with a first RF antenna inductively coupled to a first plasma source within a chamber and a second RF antenna inductively coupled to a second plasma source of within the chamber; and processing a work-piece within the chamber with the plasma from the first and second plasma sources. In some embodiments, the first and the second RF antenna are connected in parallel. In some embodiments, the first and the second RF antenna are connected to the same RF power supply and RF match unit. In some embodiments, the method further comprises distributing a process gas substantially evenly to the first and second plasma sources.

These and other aspects and embodiments of the disclosure are illustrated and described below.

### BRIEF DESCRIPTION OF THE DRAWINGS

The invention is described with reference to the following figures, which are presented for the purpose of illustration only and are not intended to be limiting.

In the Drawings:

FIG. 1 is a schematic representation of a surface treatment unit according to an illustrative embodiment.

FIGS. 2A, 2B, 2C, and 2D are schematic representations of RF antenna and plasma source configurations according to illustrative embodiments.

FIGS. 3A and 3B are representations of a gas distribution system according to an illustrative embodiment showing a side (FIG. 3A) and top (FIG. 3B) view.

FIGS. 4A, 4B, and 4C are representations of a gas distribution system according to an illustrative embodiment showing a side (FIG. 4A), top (FIG. 4B), and bottom (FIG. 4C) view.

### DETAILED DESCRIPTION OF ILLUSTRATIVE EMBODIMENTS

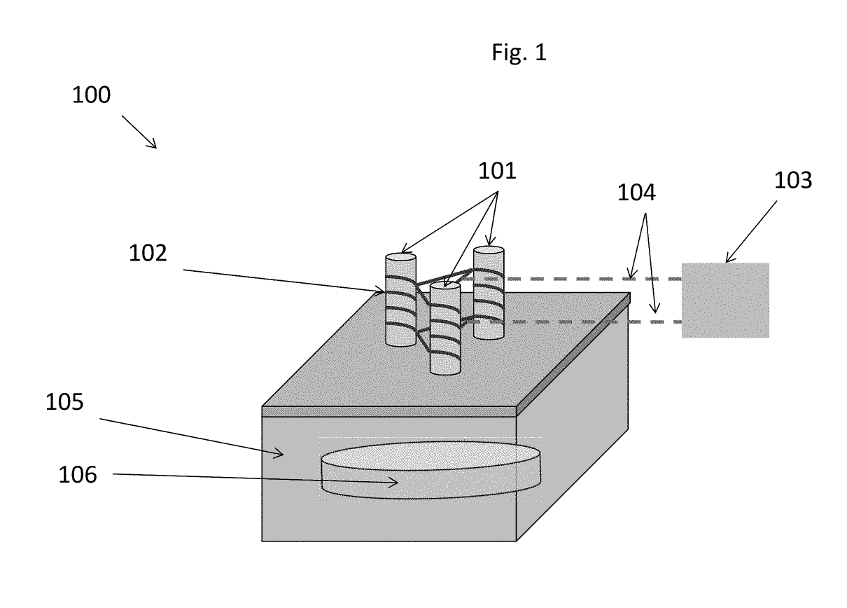

FIG. 1 is a schematic representation of a surface treatment unit 100 according to an illustrative embodiment. The surface treatment unit 100 includes one or more plasma sources 101, one or more RF antennas 102, and one or more RF units 103. The RF units 103 include one or more RF power supplies 103a (not shown) and RF match units 103b (not shown). The plasma sources 101 are inductively coupled to the RF antennas 102, which are connected to the RF power supply 103a and match unit 103b via one or more connectors 104. The surface treatment unit 100 further includes one or more chambers 105 that can contain one or more work-pieces 106. The surface treatment unit 100 can additionally include one or more downstream process gas inlets (not shown), one or more downstream injection gas ports (not shown), one or more process gas ports (not shown), one or more cooling supply ports (not shown), and one or more cooling return ports (not shown). In some embodiments, the main plasma is generated in plasma sources 101 such as glass tubes where electron/ion temperatures are relative high. The downstream injection gas ports can be used to avoid over-dissociation and/or chemical reactions between process gas and plasma sources 101.

In some embodiments, the surface treatment unit 100 creates an RF plasma using one or more plasma sources 101. For example, the surface treatment unit 100 can create an RF plasma using three plasma sources 101 as illustrated in the illustrative embodiment of FIG. 1. The surface treatment unit 100 distributes process gas to the plasma sources 101 by an equal/balanced gas distribution channels for equal gas delivery to multiple glass tubes. The RF antennas 102 powered by the RF power supply 103a and controlled by the RF match unit 103b ignite the gas to generate a plasma. The plasma flows from the plasma sources 101 onto the work-piece 106 to process the work-piece. For example, the plasma can be used to process a wafer to remove photoresist. Additionally, for example, the plasma can be used to treat the surface of a metal work-piece to oxidize the surface. In some embodiments, the plasma dissolves/dissociates reactive gases, such as O₂ gas into O, O* (excited oxygen atom) for better reacting with work-pieces. The use of multiple plasma sources 101 can provide more dissolved/excited reaction species to more efficiently treat larger work-pieces.

In some embodiments, the plasma sources 101 are glass tubes. In some embodiments, the use of multiple plasma sources 101 can be advantageous. For example, using multiple plasma sources 101 can increase plasma generation efficiency. This is because plasma in each plasma source 101 can be saturated when input power increased a certain level. The use of multiple plasma sources 101 allows more input power delivering to the plasma sources 101. Additionally, the use of multiple plasma sources 101 can help to improve process uniformity on work-pieces.

In some embodiments, the RF antennas 102 comprises RF inductive coils to convert RF power into an inductive field for plasma generation. The coils can be connected in parallel or serial or a combination of both parallel and serial. In some embodiments, the coils are preferably connected in parallel. Advantageously, this can improve the uniformity of RF power delivered to each coil while maintaining the same electrical potential at each coil's input port.

In some embodiments, the RF power supply 103a and match unit 103b comprise a power source supplying RF current at the RF antennas 102.

In some embodiments, the connectors 104 connect the RF power supply 103a and RF match unit 103b to the RF antennas 102 to supply power to the RF antennas to generate RF currents. The connectors 104 can, for example, be wires.

In some embodiments, the chamber 105 comprises a vacuum chamber where work-piece 106 will be set on a stage in the vacuum for treatment. The chamber 105 creates reactive species which flow toward to work-piece 106.

In some embodiments, the work-piece 106 can be a 300 mm wafer or pallet of work-pieces. The wafer can also be larger or smaller than 300 mm. In one or more embodiments, the surface treatment unit can provide efficient processing and uniformity for wafers of a variety of sizes, including 300 mm and larger. In some embodiments, the surface treatment unit 100 can be used to process other work-pieces 106 such as solar panels and other wafers. The work-piece 106 can be stationary or moving.

In some embodiments, a downstream process gas inlet directs process gas into the chamber. It can be desirable for process gas to disassociate in the plasma sources 101; however, some process gases such as fluorocarbon can be corrosive, so it can be preferable for the gases to disassociate in the chamber near the end of the plasma sources 101. In some embodiments, the downstream process gas inlet allows process gas to be directed into the chamber to reduce or eliminate corrosion of the plasma sources 101.

In some embodiments, multiple plasma sources 101 and RF antennas 102 are powered by one RF power supply 103a and controlled by one RF match unit 103b. Advantageously, using multiple plasma sources 102 and RF antennas 103 with one RF power supply 103a and match unit 103b can provide stable plasma generation and can reduce and/or minimize the plasma treatment unit size. Additionally, using one RF power supply 103a and match unit 103b with multiple plasma sources 102 and RF antennas 103 can reduce or eliminate cross-talk between power sources. In some embodiments, plasma sources 101 and RF antennas 102 are used with multiple RF power supplies 103a and/or match units 103b.

In the illustrative embodiment shown in FIG. 1, the RF antennas 102 are connected in parallel between each plasma source 101. By using a parallel RF antenna 102 configuration, the same potential at each plasma source 101 can be obtained. Advantageously, a parallel RF antenna connection can lower total impedance in the RF circuit, can widen RF frequency range for plasma generation, and can balance RF current flow into each antenna 102. This, in turn, can allow each plasma source 101 to produce the same plasma and to uniformly process the work-piece. In some embodiments, the RF antennas 102 are connected in series. In still further embodiments, the RF antennas 102 are connected in a combination of series and parallel.

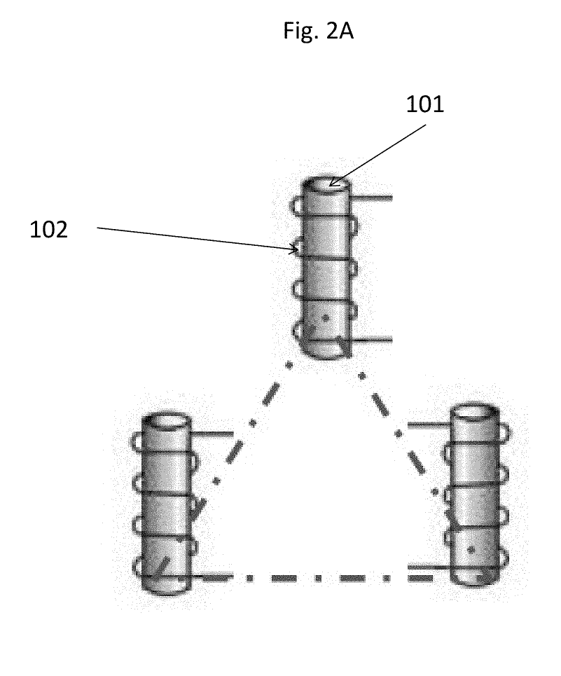

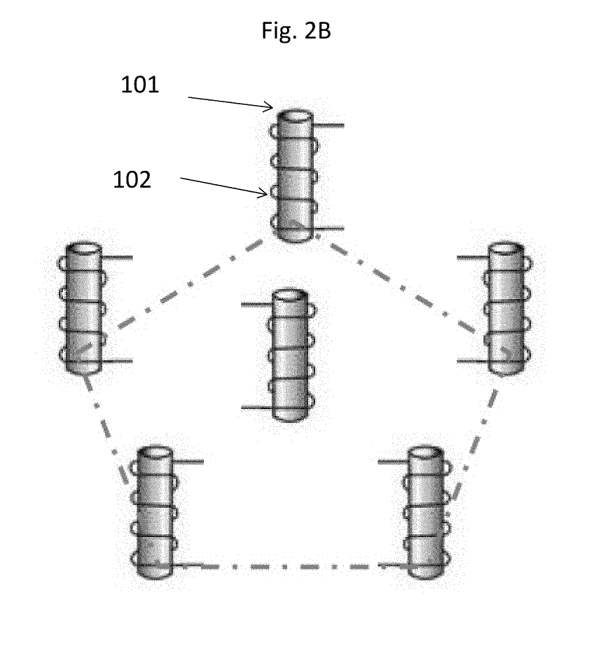

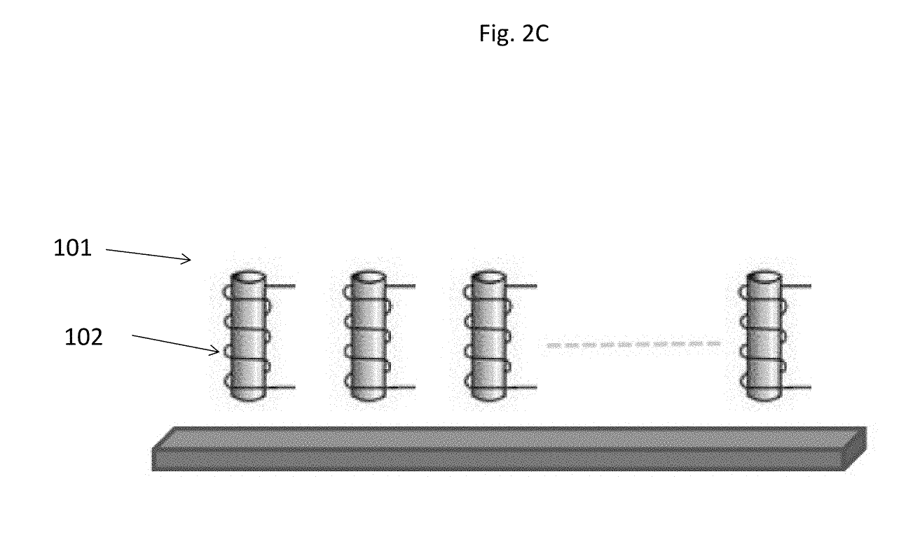

In the illustrative embodiment shown in FIG. 1, the surface treatment unit 100 includes three plasma sources 101. However, it will be appreciated that in other embodiments, one or more plasma sources can be used. Examples of additional illustrative embodiments are discussed below with respect to FIGS. 2A-2D.

In some embodiments, the use of two or more plasma sources 101 can improve efficiency and uniformity. As the power supplied to a plasma source increases, the plasma source can eventually saturate. In some embodiments, by utilizing two or more plasma sources 101, more plasma can be output to the chamber than if a single plasma source 101 were used. Additionally, in some embodiments, the plasma is more dense below the tube and less dense further away from the tube. As wafers and other work-pieces become larger, a single plasma source may provide less uniform treatment because some portions of the wafer are farther from the plasma source than others. A “shower plate” can be used to improve uniformity; however, the shower plate can absorb energy directed toward the wafer. Advantageously, in some embodiments, by utilizing multiple plasma sources 101, uniformity can be improved as compared with a single plasma source, and, uniformity can be improved without the problems associated with a shower plate.

The surface treatment unit 100 can use an RF power supply 103a and RF match unit 103b in a wide frequency range. For example, in some embodiments, the frequency can be in the range of 1-40 MHz. In some embodiments, parallel connection allows the unit to work at wide range of RF frequency. In particular, frequency (f) is related to inductance (L) and capacitance (C) by the following equation: 2πf=1/square root (LC), where total inductance L come from the RF antenna 102 and capacitance C is configured by the RF match unit 103b. In some embodiments, the range of capacitance C is preferably not too small. As such, in such embodiments, inductance L should not be too large in the RF circuit. In some embodiments, the parallel configuration helps reduce total L, whereas a serial connection would increase L.

The surface treatment unit 100 can integrate a wide range of power. For example, in some embodiments, the surface treatment unit 100 is capable of integrating with up to a 10 kW or more RF power supply 103a and RF match unit 103b. In some embodiments, the plasma generation for each plasma source 101 may be limited due to factors such as gases dissolving/dissociation, leading to saturation of the plasma source 101 above a certain RF power level. By distributing plasma across multiple plasma sources 101, the total input power saturation level can be increased.

The surface treatment unit 100 can use a variety of process gases, such as O2, N2, Ar, He, H2, among others, as well as gas mixtures with one or more of the forgoing and/or other gases.

The surface treatment unit 100 can operate over a wide range of pressures. For example, in some embodiments, the pressure can be in the range of 1 mTorr to 1 Torr. The pressure can also be higher or lower than this range.

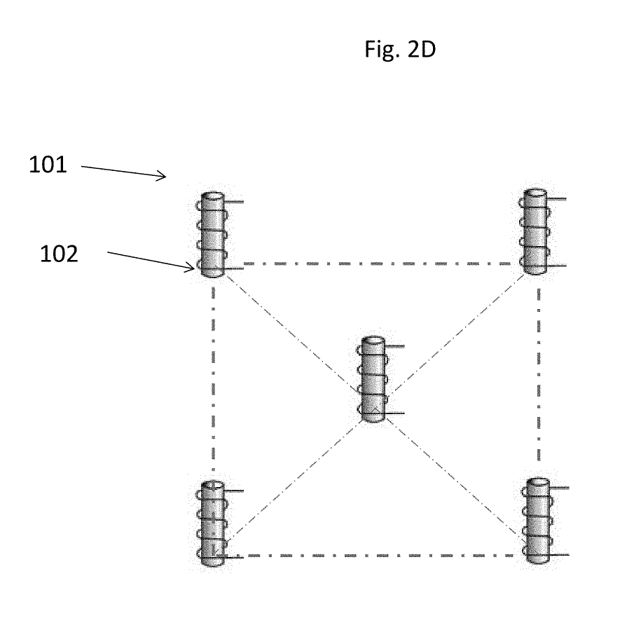

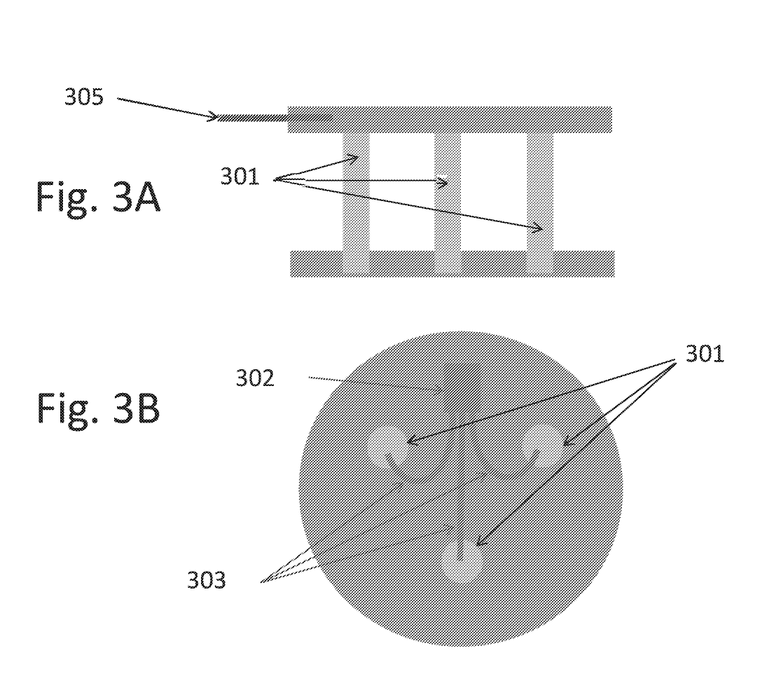

In some embodiments, the flow of process gas is controlled and distributed evenly to some or all of the plasma sources 101. In some embodiments, to achieve good process uniformity, uniform (or equal reactive species in each tube) is desirable. In such embodiments, input gas flow to each tube should be equal. FIGS. 3A and 3B illustrate the use of equal gas flow paths according to an exemplary embodiment. FIGS. 3A and 3B illustrate an exemplary case of equal distribution of gases among three tubes 301 from a gas inlet 305 via a gas input unit 302 and gas flow passes 303; however, a person of skill in the art will appreciate that in other embodiments, more or fewer tubes can be used. As illustrated in FIG. 3B, the gas flow passes 303 can be arranged, for example, in a spiral shape to make sure gas delivery paths have the same length from gas input unit 302 to each tube 301 center. In some embodiments, the gas flow to each tube can be varied with different amounts of gas distributed to each tube.

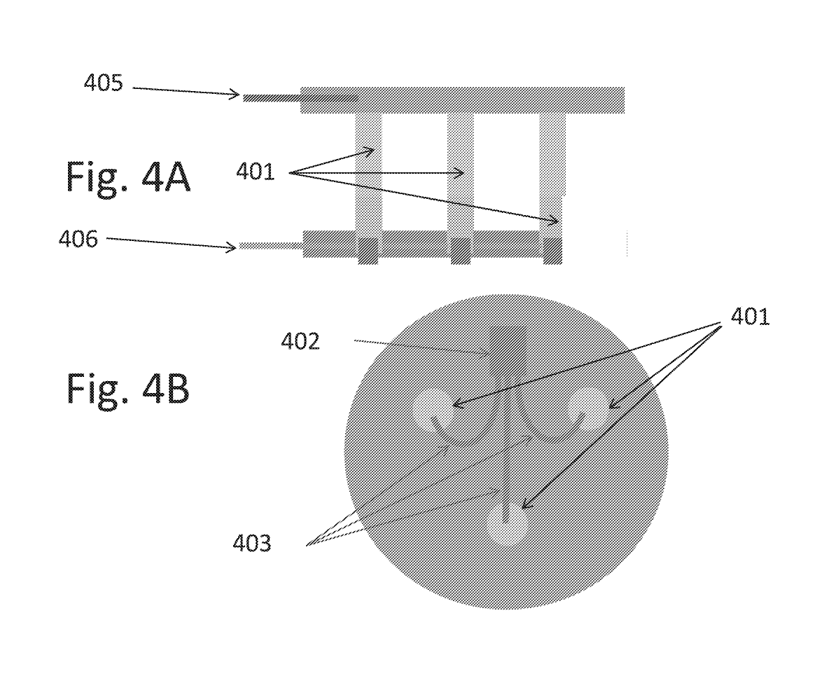

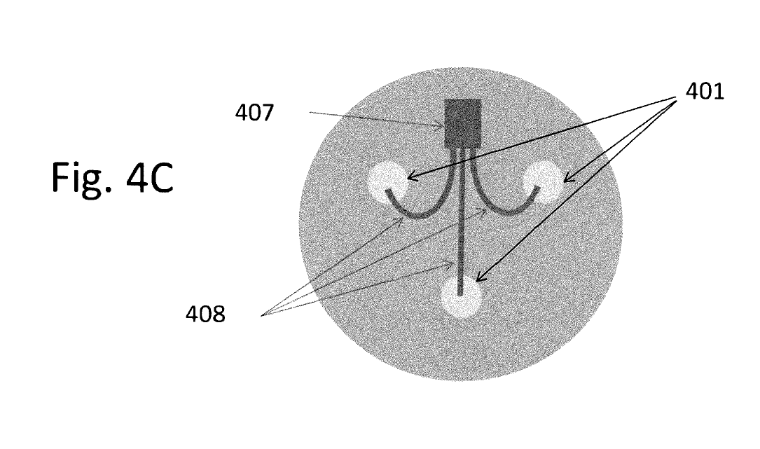

FIGS. 4A, 4B, and 4C show an exemplary case according to some embodiments of distribution of gases among three tubes 401 from a main process gas inlet 405 and a second process gas inlet 406; however, a person of skill in the art will appreciate that in other embodiments, more or fewer tubes can be used. In some embodiments, a main process gas is distributed among the three tubes 401 from the main process gas inlet 405 via an upper gas input unit 402 and upper gas flow passes 403 as illustrated in FIGS. 4A and 4B. In some embodiments, a second process gas is distributed among the three tubes 401 from the second process gas inlet 406 via a lower gas input unit 407 and lower gas flow passes 408 as illustrated in FIGS. 4A and 4C. In some embodiments, the main process gas inlet 405 has an equal gas distribution path to evenly distribute the main process gas among the tubes 401. In some embodiments, the second process gas inlet 406 has an equal gas distribution path to evenly distribute the second process gas among the tubes 401. In some embodiments, the second process gas inlet 406 has an equal gas delivery path as main gas inlet 405. In some embodiments, upper gas flow passes 403 can be arranged, for example, in a spiral shape to make sure gas delivery paths have the same length from the upper gas input unit 402 to each tube 401 center as illustrated in FIG. 4B. In some embodiments, lower gas flow passes 408 can be arranged, for example, in a spiral shape to make sure gas delivery paths have the same length from lower gas input unit 408 to each tube 401 center as illustrated in FIG. 4C. In some embodiments, the gas flow to each tube can be varied with different amounts of gas distributed to each tube.

In some embodiments, the main gas inlet 405 for major process gas goes through plasma sources 401 where process gases will be dissociated/dissolved efficiently, for example, to make Oxygen atoms and ions from 0₂ gas. In some embodiments, the second process gas inlet 406 allows a low level of gas dissociation for sample treatment. For example, in some embodiments, the level of gas dissociation comprises changes such the change from H₂ (hydrogen) to excited state of H₂* without generating too many H atoms and/or the change from CF₄ to CFx (x=1, or 2, or 3) without generating too many C and F atoms.

The surface treatment unit 100 can be used in a variety of applications. For example, it can be used for semiconductor and oxidation processes and applications such as metal oxide coating at plastic surface for protection and coloring, semiconductor wafer surface treatment, and large semi-chip packaging plate surface treatment, among others.

FIGS. 2A, 2B, 2C, and 2D are schematic representations of configurations of RF antennas 102 and plasma sources 101 according to illustrative embodiments. FIG. 2A shows a schematic representations of an illustrative embodiment with RF antenna 102 and plasma source 101 in a triangle configuration. The RF antenna 102 and plasma source 101 can be connected in parallel, in series, or in a combination of series and parallel. FIG. 2A shows an example with three plasma RF antennas 102 and plasma sources 101, but it will be appreciated that in some embodiments, the triangle configuration can have more than three plasma RF antennas 102 and plasma sources 101. Additionally, in some embodiments, the triangle configuration can include one or more plasma sources 101 and RF antennas 102 within the triangle.

FIG. 2B shows a schematic representations of an illustrative embodiment with RF antenna 102 and plasma source 101 in a pentagon configuration. The RF antenna 102 and plasma source 101 can be connected in parallel, in series, or in a combination of series and parallel. FIG. 2B shows an example with five plasma RF antennas 102 and plasma sources 101 in the pentagon, but it will be appreciated that in some embodiments, the pentagon configuration can have more than five plasma RF antennas 102 and plasma sources 101. Additionally, in some embodiments, the pentagon configuration can include a plasma source 101 and RF antenna 102 within the pentagon, as shown in FIG. 2B. In some embodiments, the pentagon configuration can include more than one RF antenna 102 and plasma source 101 within the pentagon, and in some embodiments, there is no RF antenna 102 or plasma source 101 within the pentagon.

FIG. 2C shows a schematic representations of an illustrative embodiment with RF antenna 102 and plasma source 101 in a linear configuration. The RF antenna 102 and plasma source 101 can be connected in parallel, in series, or in a combination of series and parallel. In some embodiments, the linear configuration can have two or more RF antennas 102 and plasma sources 101.

FIG. 2D shows a schematic representations of an illustrative embodiment with RF antenna 102 and plasma source 101 in a rectangular configuration. The RF antenna 102 and plasma source 101 can be connected in parallel, in series, or in a combination of series and parallel. FIG. 2D shows an example with four plasma RF antennas 102 and plasma sources 101 in the rectangular configuration, but it will be appreciated that in some embodiments, the rectangular configuration can have more than four plasma RF antennas 102 and plasma sources 101. Additionally, in some embodiments, the rectangular configuration can include one or more plasma sources 101 and RF antennas 102 within the rectangle.

The number of plasma sources and the spacing of the plasma sources is configurable based on the application. In general, is desirable to use more tubes for larger work-pieces. The density of dissolved/dissociated reactive species is high near the tube. By using multiple tubes, greater uniformity can be achieved by increasing the portion of the work-piece that is near the center of a tube.

For example, triangle and pentagon configurations such as those shown in FIGS. 2A and 2B can improve efficiency and uniformity when processing a round work-piece 106 such as a round wafer by locating a larger portion of the wafer near the centers of the tubes.

As a further example, a linear configuration of plasma sources 101 and RF antennas 102 such as the configuration show in FIG. 2C can improve efficiency when processing a long, rectangular workpiece by increasing the area of the workpiece that is near the centers of the tubes.

As an additional example, a rectangular configuration of plasma sources 101 and RF antennas 102 such as the configuration shown in FIG. 2D can improve efficiency when processing a square or rectangular work-piece 106 such as a rectangular glass wafer or a flat panel display by increasing the area of the workpiece that is near the centers of the tubes.

In some embodiments, the surface treatment unit 100 is configured to fit onto vacuum chamber lids and/or side walls. In some embodiments, this allows the plasma processing to occur in a vacuum, with pressures ranging, e.g. from 1 to several 100 mTorr.

It will be appreciated that while a particular sequence of steps has been shown and described for purposes of explanation, the sequence may be varied in certain respects, or the steps may be combined, while still obtaining the desired configuration. Additionally, modifications to the disclosed embodiment and the invention as claimed are possible and within the scope of this disclosed invention.

1. A surface treatment unit comprising:
a chamber;
a process gas inlet configured to allow process gas to enter the chamber;
a first and a second plasma source; and
a first RF antenna inductively coupled to the first plasma source and a second RF antenna inductively coupled to the second plasma source, wherein the first and second RF antennas are configured to simultaneously ignite a first and second plasma, and wherein the first and second plasma sources are configured to simultaneously supply the first and second plasma to a work-piece within the chamber.

2. The surface treatment unit of claim 1, wherein the first and the second RF antenna are connected in parallel.

3. The surface treatment unit of claim 1, wherein the first and the second RF antenna are configured to be connected to the same RF power supply and RF match unit.

4. The surface treatment unit of claim 1, wherein the gas inlet is configured to distribute a process gas substantially evenly to the first and second plasma sources.

5. The surface treatment unit of claim 1, further comprising:
a third plasma source; and
a third RF antenna inductively coupled to the third plasma source, wherein the third RF antenna is configured to ignite a third plasma, and wherein the third plasma source is configured to supply the third plasma to a work-piece within the chamber.

6. The surface treatment unit of claim 5, wherein the first, second, and third plasma sources and the RF antennas are arranged in a triangle configuration.

7. The surface treatment unit of claim 5, where the first, second, and third plasma sources and the RF antennas are arranged in a linear configuration.

8. The surface treatment unit of claim 5, further comprising:
a fourth plasma source; and
a fourth RF antenna inductively coupled to the fourth plasma source, wherein the fourth RF antenna is configured to ignite a fourth plasma, and wherein the fourth plasma source is configured to supply the fourth plasma to a work-piece within the chamber, and wherein the first, second, third, and fourth plasma sources and the RF antennas are arranged in a rectangular configuration.

9. The surface treatment unit of claim 5, further comprising:
a fourth plasma source;
a fourth RF antenna inductively coupled to the fourth plasma source, wherein the fourth RF antenna is configured to ignite a fourth plasma, and wherein the fourth plasma source is configured to supply the fourth plasma to a work-piece within the chamber;
a fifth plasma source; and
a fifth RF antenna inductively coupled to the fifth plasma source, wherein the fifth RF antenna is configured to ignite a fifth plasma, and wherein the fourth plasma source is configured to supply the fourth plasma to a work-piece within the chamber, and wherein the first, second, third, fourth, and fifth plasma sources and the RF antennas are arranged in a pentagon configuration.

10. The surface treatment unit of claim 9, further comprising:
a sixth plasma source; and
a sixth RF antenna inductively coupled to the sixth plasma source, wherein the sixth RF antenna is configured to ignite a sixth plasma, wherein the sixth plasma source is configured to supply the sixth plasma to a work-piece within the chamber, and wherein the sixth plasma source and the sixth RF antenna are positioned within the pentagon configuration.

11. The surface treatment unit of claim 1, wherein the process gas inlet is an upper process gas inlet and the process gas is a main process gas, further comprising:
a lower process gas inlet configured to allow a second process gas to enter the chamber.

12. The surface treatment unit of claim 11, wherein the upper gas inlet is configured to distribute the main process gas substantially evenly to the first and second plasma sources; and wherein the lower process gas inlet is configured to distribute the second process gas substantially equally to the first and second plasma sources.

13. A method of processing a work-piece comprising:
simultaneously igniting a first and a second plasma with a first RF antenna inductively coupled to a first plasma source within a chamber and a second RF antenna inductively coupled to a second plasma source of within the chamber; and
processing a work-piece within the chamber with the plasma from the first and second plasma sources.

14. The method of claim 13, where the first and the second RF antenna are connected in parallel.

15. The method of claim 13, wherein the first and the second RF antenna are connected to the same RF power supply and RF match unit.

16. The method of claim 13, further comprising distributing a process gas substantially evenly to the first and second plasma sources.
